(19) United States
(12) Patent Application Publication
(10) Pub. No.: US 2024/0124350 A1
(43) Pub. Date: Apr. 18, 2024

(54) QUANTUM DOT COMPOSITE STRUCTURE AND A FORMING METHOD THEREOF

(71) Applicant: Lextar Electronics Corporation, Hsinchu City (TW)

(72) Inventors: Ching LIU, Hsinchu City (TW); Wen-Tse HUANG, Hsinchu City (TW); Ru-Shi LIU, Hsinchu City (TW); Pei Cong YAN, Hsinchu City (TW); Chai-Chun HSIEH, Hsinchu City (TW); Hung-Chun TONG, Hsinchu City (TW); Yu-Chun LEE, Hsinchu City (TW); Tzong-Liang TSAI, Hsinchu City (TW)

(21) Appl. No.: 18/486,426

(22) Filed: Oct. 13, 2023

(30) Foreign Application Priority Data
Oct. 17, 2022 (TW) 111139203

(51) Int. Cl. C03C 14/00; C03B 19/10; C03C 4/12; C03C 12/00; C03C 17/245; C03C 17/25; C03C 17/34; C23C 16/40; C23C 16/44; C23C 16/455

(52) U.S. Cl. CPC C03C 14/006; C03B 19/1005; C03C 4/12; C03C 12/00; C03C 17/245; C03C 17/25; C03C 17/3417; C23C 16/402; C23C 16/403; C23C 16/4417; C23C 16/45553; C23C 16/45555; B82Y 20/00; C03C 2204/00; C03C 2214/16

(57) ABSTRACT

A quantum dot composite structure and a method for forming the same are provided. The quantum dot composite structure includes: a glass particle including a glass matrix and a plurality of quantum dots located in the glass matrix, wherein at least one of the plurality of quantum dots includes an exposed surface in the glass matrix; and an inorganic protective layer disposed on the glass particle and covering the exposed surface.

### TECHNICAL FIELD

The disclosure relates to a quantum dot composite structure and a forming method thereof, and in particular, it relates to a quantum dot composite structure with a protective layer and a forming method thereof.

### CROSS REFERENCE TO RELATED APPLICATIONS

This application claims priority of Taiwan Patent Application No. 111139203, filed on Oct. 17, 2022, and the content of the entirety of which is incorporated by reference herein.

### BACKGROUND

### Description of the Related Art

Due to quantum confinement effect, the emission spectrum of quantum dots can be adjusted according to the particle size, and has a characteristic with a narrow full width at half maximum (FWHM) to provide high-purity color light. The applications of quantum dots are wide, such as light emitting diodes, solar cells, lighting devices, biomarkers and displays.

Despite that, quantum dots are susceptible to the presence of water and oxygen in the environment, which makes the quantum dots less stable and reduces the luminous effect. Although the current quantum dots and the forming method thereof have gradually met the intended uses, they still do not completely meet the requirements in all aspects.

### SUMMARY

An embodiment of the present disclosure provides a quantum dot composite structure. The quantum dot composite structure includes: a glass particle including a glass matrix and a plurality of quantum dots located in the glass matrix, wherein at least one of the plurality of quantum dots includes an exposed surface in the glass matrix; and an inorganic protective layer disposed on the glass particle and covering the exposed surface.

An embodiment of the present disclosure provides a method of forming a quantum dot composite structure comprising: providing a glass particle comprising a plurality of quantum dots; forming a first protective layer on the glass particle by an atomic layer deposition (ALD) process to make the first protective layer cover the glass particle conformally; and forming a second protective layer on the first protective layer by a sol-gel process to make the second protective layer cover the first protective layer.

The quantum dot composite structure and the forming method thereof of the present disclosure are able to be applied on various electronic devices. In order to make the features and advantages of the present disclosure more readily be understood, various embodiments are given in the subsequent description in conjunction with the accompanying drawings.

### BRIEF DESCRIPTION OF THE DRAWINGS

Aspects of the present disclosure are better understood from the following detailed description when read with the accompanying figures. It is worth noting that some features may not be drawn to scale in accordance with the standard practice in the industry. In fact, the dimensions of the various features may be arbitrarily increased or reduced for clarity of discussion.

FIG. 1 illustrates a perspective schematic view of a glass bulk according to some embodiments of the present disclosure.

FIGS. 2-4 respectively illustrate perspective schematic views of various quantum dot composite structures according to some embodiments of the present disclosure.

FIG. 5 illustrates an X-ray diffraction analysis pattern of various stages in a method of forming a quantum dot composite structure according to some embodiments of the present disclosure.

FIG. 6 illustrates fluorescence spectrums of various stages in a method of forming a quantum dot composite structure according to some embodiments of the present disclosure.

FIGS. 7-8 respectively illustrate hydrophobicity test images of various stages in a method of forming a quantum dot composite structure according to some embodiments of the present disclosure.

FIGS. 9-12 respectively illustrate scanning electron microscope (SEM) images of various stages in a method of forming a quantum dot composite structure according to some embodiments of the present disclosure.

FIG. 13 illustrates an infrared absorption spectrum of various stages in a method of forming a quantum dot composite structure according to some embodiments of the present disclosure.

FIGS. 14-15 respectively illustrate transmission electron microscopy (TEM) images of various stages in a method of forming a quantum dot composite structure according to some embodiments of the present disclosure.

FIG. 16 is a schematic view of a light-emitting device according to some embodiments of the present disclosure.

FIG. 17 is a schematic view of a light-emitting device according to some embodiments of the present disclosure.

### DETAILED DESCRIPTION

The following disclosure provides many different embodiments, or examples, for implementing different features of the provided quantum dot composite structures. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the disclosure may repeat symbols and/or characters of components in different embodiments or examples. This repetition is for simplicity and clarity, rather than to represent the relationship between the different embodiments and/or examples discussed.

Further, spatially relative terms, such as “above,” “upper,” “beneath,” “below,” “lower,” left,” “right,” and the like, may be used herein for ease of description to describe one element or feature's relationship to another element(s) or feature(s) as illustrated in the figures. Therefore, spatially relative terms are intended to illustrate rather than limit this disclosure. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some embodiments of the present disclosure, the terms regarding disposing or connecting such as “on,” “connected to,” “coupled to”, or other similar terms, unless specifically defined, may mean that two components are in direct contact, or mean that two components are not in direct contact which includes the case where another component is interposed between them. The terms regarding disposing or connecting may also include the case where both structures are movable or both structures are fixed.

In addition, in the specification or the claims, ordinal numbers such as “first”, “second”, and other similar terms are used to name different components or distinguish different embodiments or scopes, not to limit the upper or lower limit of the number of components, nor to limit the manufacturing sequence of components or disposing sequence of components.

Here, the terms “about”, “approximately”, “substantially” usually mean within 10%, within 5%, or within 3%, within 2%, within 1% or within 0.5% of a given value or range. Here, the given value is an approximate number. That is, in the absence of a specific description of “about”, “approximately”, “substantially”, the meaning of “about”, “approximately”, “substantially” may still be implied.

Unless otherwise defined, all terms (including technical and scientific terms) used herein have the same meaning as commonly understood by a person skilled in the art to which the invention pertains. It will be further understood that terms, such as those defined in commonly used dictionaries, should be interpreted as having a meaning consistent with the relevant technology and the context or background of the present disclosure and will not be interpreted in an idealized or overly formal sense unless expressly so defined herein.

Different embodiments disclosed below may reuse the same reference symbols and/or labels. These repetitions are for the purpose of simplicity and clarity and are not intended to limit the specific relationship between the various embodiments and/or structures discussed below. It is understood that additional steps can be provided before, during, and after the steps of method, and some of the steps described can be replaced or eliminated for other embodiments of the method.

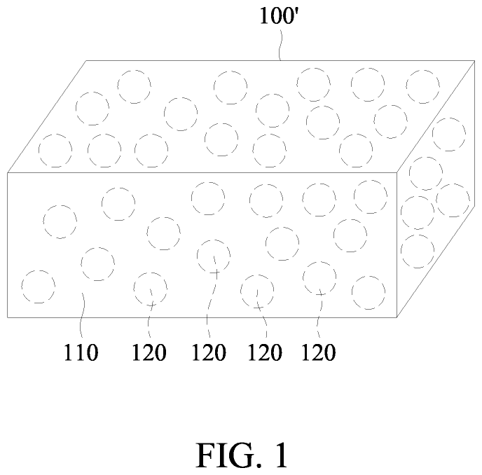

FIG. 1 illustrates a perspective schematic view of a glass bulk 100′ according to some embodiments of the present disclosure. In some embodiments, the glass bulk 100′ may comprise a glass matrix 110 and a plurality of quantum dots 120, as shown in FIG. 1. In other words, the glass bulk 100′ may be a bulk having the quantum dots 120 embedded in the glass matrix 110. In some embodiments, the glass bulk 100′ may be a cuboid, but the present disclosure is not limited to this. In some embodiments, the glass matrix 110 may be formed by a melt-quench process. In some embodiments, since the plurality of quantum dots 120 may be embedded in the glass matrix 110 and the glass matrix 110 has rigidity and hydrophobicity, the glass matrix 110 can improve the moisture resistance and oxygen resistance of the quantum dots 120, thereby improving the stability and reliability of the quantum dots 120.

In some embodiments, the glass matrix 100 comprises phosphosilicate glass, tellurite glass, borosilicate glass, borogermanate glass or combinations thereof, but the present disclosure is not limited to these embodiments. Examples of the plurality of quantum dots 120 comprise semiconductor materials of Group II-VI, Group III-V, Group IV-VI, and/or Group IV. Examples of the quantum dots 120 comprise cadmium-based quantum dots, such as cadmium sulfide (CdS), cadmium-free quantum dots such as indium phosphide (InP), inorganic perovskite quantum dots, other suitable quantum dots or any combination thereof. For instance, the quantum dots 120 may CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, HgZnSTe, GaN, GaP, GaAs, GaSb, AN, AlP, AlAs, AlSb, InN, InP, InAs, InSb, GaNP, GaNAs, GaNSb, GaPAs, GaPSb, AlNP, AINAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, SnPbSTe, CsPbCl₃, CsPbBr₃, CsPbI₃, Cs₄PbCl₆, Cs₄PbBr₆, Cs₄PbI₆, or CsPbX₃/Cs₄PbX₆ wherein X is Cl, Br, I. The quantum dots 120 may be excited by short wavelength light (high energy), such as blue light or UV light, to emit light with longer wavelength light (low energy). In some embodiments, the blue light may be provided by a blue light emitting diode and the UV light may be provided by a UV light emitting diode. In some embodiments, under the excitation of blue light or UV light, the light emission wavelength of the quantum dots 120 is greater than or equal to 300 nm and less than or equal to 800 nm.

In some embodiments, take the glass bulk 100′ having perovskite quantum dots as an example to explain. In some embodiments, after weighing the powder of the below chemicals according to the below proportion, the powder is ground and mixed evenly to obtain a powder mixture. In one embodiment, the composition of the chemicals is as follows: 25.71 mol of SiO₂, 42.55 mol of B₂O₃, 16.12 mol of ZnO, 6.84 mol of SrCO₃, 2.04 mol of K₂CO₃, 1.02 mol of BaCO₃, 0.30 mol of Sb₂CO₃, 2.86 mol of Cs₂CO₃, 5.72 mol of PbBr 2 and 5.72 mol NaBr. Then, the power mixture is put into a platinum crucible or alumina crucible, and put into a muffle furnace to be melted at 1200° C. for 15 minutes. When the powder mixture has completely melted into liquid, the molten liquid is poured onto the brass mold or graphite mold which has been preheated to 350° C., and the molten liquid and the mold are quickly sent together into the muffle furnace for annealing at 350° C. for 3 hours to obtain a precursor glass of the glass bulk 100′. Then, the precursor glass is sent to a muffle furnace for heat treatment at 470° C. to 570° C. for 10 hours, so that the perovskite quantum dots 120 can crystallize within the glass matrix 110 to form the glass bulk 100′.

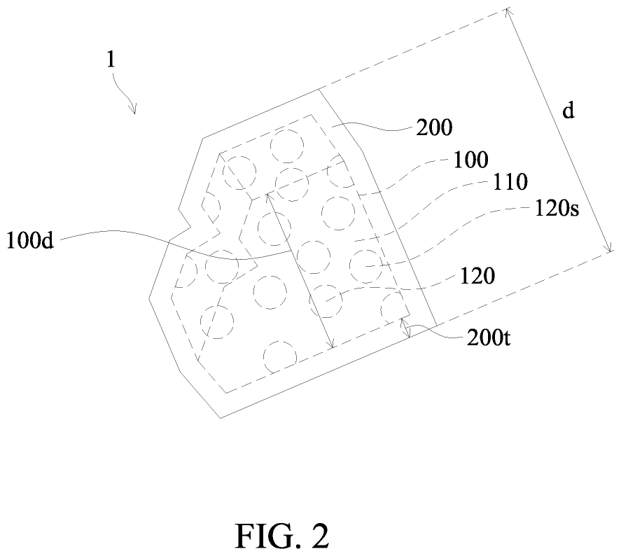

FIG. 2 illustrates a perspective schematic view of a quantum dot composite structure 1 according to some embodiments of the present disclosure.

In some embodiments, in order to utilize the glass bulk 100′ as shown in FIG. 1, the glass bulk 100′ is ground into glass particles 100 (glass powder) as shown in FIG. 2 first so the glass particles 100 can be applied to an LED package structure or a display. Hence, in some embodiments, the grinding process may be performed on the glass bulk 100′ so that the glass bulk 100′ is broken and dispersed into a plurality of glass particles 100. In some embodiments, the grinding process may use a mortar to grind uniformly, but the present disclosure is not limited to this.

Then, in some embodiments, the particle size screening process may be performed on the plurality of glass particles 100 to make the particle size distribution more concentrated. In some embodiments, an average diameter 100d of the glass particles 100 is obtained by taking a microscopic image of the glass particles 100 with a scanning electron microscope (SEM) and a diameter value of each glass particles 100 is estimated by an image analysis software (such as Image J). Therefore, the average diameter of the glass particles 100 can be calculated. In some embodiments, the particle size screening process may include or may be a filtration process, a gravity sedimentation process, a centrifugation process, other suitable screening processes or a combination thereof, but the present disclosure is not limited to these embodiments. In some embodiments, the average diameter 100d of the glass particles 100 may be greater than or equal to 20 μm and less than or equal to 50 μm. For example, the average diameter 100d of the glass particles 100 may be 20 μm, 25 μm, 30 μm, 35 μm, 40 μm, 45 μm, 50 μm, or a value or range between any two of the aforementioned values, but the present disclosure is not limited to these. In some embodiments, if the average diameter 100d of the glass particles 100 is greater than 50 μm, it may cause the encapsulation process difficult to complete. If the average diameter 100d of the glass particles 100 is less than 20 μm, the glass matrix 110 may be damaged and the absorption of the glass particles 100 to the excitation light source is affected, whereby the quantum dots 120 can be closer to or exposed to the surface of the glass particles 100 so the quantum dots 120 are more susceptible to water or oxygen which may impact the quantum efficiency of the quantum dots 120.

In some embodiments, approximately 2.5 g of glass particles 100 can be weighed and placed in a beaker, and 30 mL of ethanol can be added to the beaker. The glass particles 100 and ethanol are stirred at a room temperature such as 25° C. for 30 minutes. After stop stirring, wait for about 2 minutes for the glass particles 100 with larger particle size to be settled to the bottom while glass particles 100 with smaller particle size are suspended in the ethanol. Then, use a dropper to remove the upper suspension and filter out the smaller glass particles 100. This step is repeated multiple times until the particle size of glass particles 100 is greater than or equal to 20 μm and less than or equal to 50 μm. For example, the above step can be repeated for four times to obtain the glass particles 100 through the particle size screening process.

In some embodiments, since the glass particles 100 may have an irregular profile after the grinding process and particle size screening process, the glass matrix 110 of the glass particles 100 may expose an exposed surface 120S of at least one of the plurality of quantum dots 120. That is to say, the surface of the glass particles 100 is prone to be cracked during the grinding process so a part of the surface of the quantum dots 120 is exposed and cause the quantum dots 120 to be degraded by the environmental factors such as moisture and/or oxygen.

In order to protect the quantum dots 120 from being affected by external substances such as moisture or oxygen, in some embodiments, an inorganic protective layer 200 is formed on the surface of the glass particles 100 to cover the exposed surface 120S of the quantum dots 120 as shown in FIG. 2, thereby obtaining the quantum dot composite structure 1. Because the inorganic protective layer 200 covers the exposed surface 120S of quantum dots 120, the carrier transmission efficiency and/or luminescence efficiency of quantum dots 120 in the quantum dot composite structure 1 can be maintained or not be affected. Therefore, the inorganic protective layer 200 can improve the resistance to moisture and oxygen, the hydrophobicity of the quantum dot composite structure 1, and/or extend the application range of the quantum dot composite structure 1, such as used in high humidity environments.

In some embodiments, the inorganic protective layer 200 may be a single layer or a plurality of layers. In some embodiments, the inorganic protective layer 200 can be formed by an atomic layer deposition (ALD) process, a sol-gel process, other suitable processes, or a combination thereof. In some embodiments, the inorganic protective layer 200 may be a single layer or a plurality of layers formed by the ALD process and conformally formed on the surface of the glass particles 100 in accordance with the shape of the glass particles 100. In other embodiments, the inorganic protective layer 200 may be a single layer or a plurality of layers formed by the sol-gel process. In this embodiment, the inorganic protective layer 200 is formed on the glass particles 100. In other embodiments, the inorganic protective layer 200 may include different layers formed by the ALD process and the sol-gel process, respectively. Since the inorganic protective layer 200 can be formed by the ALD process and/or the sol-gel process, the inorganic protective layer 200 can be formed on the glass particles 100 under formation conditions such as the formation temperature that do not damage the internal crystal structure of the quantum dots 120 in the glass particles 100. Therefore, after forming the inorganic protective layer 200, the characteristics of quantum dots 120 such as high color purity, high quantum efficiency, and an emission spectrum with narrow full width at half maximum can still be maintained.

In some embodiments, the reaction temperature of the ALD process and/or the sol-gel process can be greater than or equal to 60° C. and less than or equal to 180° C. For example, the reaction temperature of the ALD process and/or the sol-gel process can be, but not limited to, 60° C., 70° C., 80° C., 90° C., 100° C., 110° C., 120° C., 130° C., 140° C., 150° C., 160° C., 170° C., 180° C., or a value or range between any two of the aforementioned values. In some embodiments, the reaction temperature of the ALD process can be greater than or equal to 75° C. and less than or equal to 90° C. In some embodiments, the reaction temperature of the sol-gel process may be greater than or equal to 75° C. and less than or equal to 90° C.

In some embodiments, the inorganic protective layer 200 may include or be, but not limited to, inorganic oxide. In some embodiments, the inorganic protective layer 200 may include or be, but not limited to, titanium oxide (TiO₂), silicon oxide (SiO₂), aluminum oxide (Al₂O₃), zirconia (ZrO₂), other suitable oxides or any combination thereof. In some embodiments, the inorganic protective layer 200 may include a plurality of layers, and the plurality of layers include the same material formed by different processes. Although the plurality of layers includes the same material, each layer has different characteristics because of different formation processes. For example, the inorganic protective layer 200 may include silicon oxide formed by the ALD process and silicon oxide formed by the sol-gel process.

In some embodiments, the thickness 200t of the inorganic protective layer 200 may be greater than or equal to 1 nm and less than or equal to 500 nm. For example, the thickness 200t of the inorganic protective layer 200 can be, but not limited to, 1 nm, 50 nm, 100 nm, 150 nm, 200 nm, 250 nm, 300 nm, 350 nm, 400 nm, 450 nm, 500 nm, or a value or range between any two of the aforementioned values. In some embodiments, if the thickness of the inorganic protective layer 200 is greater than 500 nm, it may decrease the carrier transmission efficiency and cause poor luminescence efficiency of quantum dot 120. If the thickness of the inorganic protective layer 200 is less than 1 nm, it may not be able to effectively protect quantum dot 120 from degradation due to environmental factors. In some embodiments, the average diameter d of the quantum dot composite structure 1 containing inorganic protective layer 200 can be greater than or equal to 20.002 μm and less than or equal to 51 μm. For example, the average diameter d of the quantum dot composite structure 1 can be 21 μm, 25 μm, 30 μm, 35 μm, 40 μm, 45 μm, 50 μm, 51 μm, or a value or range between any two of the aforementioned values.

In some embodiments, the inorganic protective layer 200 may be composed of a plurality of layers. The total thickness of these plurality of layers should not exceed 500 nm for avoiding the problem of excessive thickness causing a decrease in carrier transmission efficiency and poor luminescence efficiency of quantum dots.

For convenience of explanation, the same or similar component symbols will not be repeated.

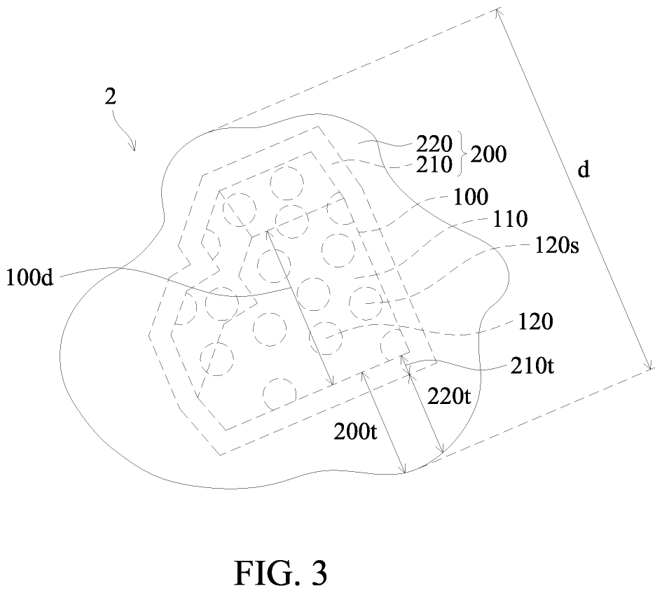

FIG. 3 is a perspective schematic view showing the quantum dot composite structure 2 according to some embodiments of the present disclosure. As shown in FIG. 3, in some embodiments, the inorganic protective layer 200 of the quantum dot composite structure 2 may include a first protective layer 210 and a second protective layer 220. In some embodiments, the first protective layer 210 can cover the glass particle 100 and directly contact the exposed surface 120S of the quantum dots 120. In some embodiments, the first protective layer 210 is conformal to the shape of the glass particle 100. That is, the first protective layer 210 is formed on the surface of the glass particles 100 in accordance with the shape of the glass particle 100. In some embodiments, the second protective layer 220 may be disposed on the first protective layer 210, and the first protective layer 210 may be between the glass particle 100 and the second protective layer 220. In some embodiments, the second protective layer 220 covers the first protective layer 210.

In some embodiments, the material and formation method of the first protective layer 210 and/or the second protective layer 220 may be the same or different from the material and formation method of the inorganic protective layer 200 mentioned above. In some embodiments, the first protective layer 210 and the second protective layer 220 may include the same or different materials. In some embodiments, since the first protective layer 210 is formed by the ALD process, the first protective layer 210 is relatively dense. The second protective layer 220 is formed by the sol-gel process so the second protective layer 220 is relatively loose (not dense) compared with the first protective layer 210. Therefore, the thickness 210t of the first protective layer 210 can be less than the thickness 220t of the second protective layer 220.

In some embodiments, the thickness 210t of the first protective layer 210 may be greater than or equal to 1 nm and less than or equal to 100 nm. For example, the thickness 210t of the first protective layer 210 can be, but not limited to, 1 nm, 10 nm, 20 nm, 30 nm, 40 nm, 50 nm, 60 nm, 70 nm, 80 nm, 90 nm, 100 nm, or a value or range between any two of the aforementioned values. In some embodiments, if the thickness 210t of the first protective layer 210 is greater than 100 nm, it may decrease the luminous efficiency of the quantum dots 120. If the thickness 210t of the first protective layer 210 is less than 1 nm, it may not be able to effectively shield the quantum dots 120 from moisture and/or oxygen.

In some embodiments, the thickness 220t of the second protective layer 220 may be greater than or equal to 10 nm and less than or equal to 500 nm. For example, the thickness 220t of the second protective layer 220 can be, but not limited to, in the range of 10 nm, 50 nm, 100 nm, 150 nm, 200 nm, 250 nm, 300 nm, 350 nm, 400 nm, 450 nm, 500 nm, or a value or range between any two of the aforementioned values. In some embodiments, if the thickness of the second protective layer 220 is greater than 500 nm, it may decrease the luminous efficiency of the quantum dots 120. If the thickness of the second protective layer 220 is less than 10 nm, it may not be able to effectively block moisture and/or oxygen.

In some embodiments, the sum of the thickness 210t of the first protective layer 210 and the thickness 220t of the second protective layer 220 can be less than or equal to 500 nm in order to avoid the problem of excessive thickness causing a decrease in carrier transmission efficiency and poor luminescence efficiency of quantum dots. In some embodiments, the first protective layer comprises a plurality of sublayers, and the sum of the thickness of the sublayers and the thickness 220t of the second protective layer 220 is less than or equal to 500 nm.

In some embodiments, the density of the first protective layer 210 may be greater than that of the second protective layer 220. For example, the number of oxide molecules per unit volume of the first protective layer 210 is greater than that of the second protective layer 220. In some embodiments, the density of the first protective layer 210 may be greater than 1 g/cm³, and the density of the second protective layer 220 may be less than 1 g/cm³. Therefore, the first protective layer 210 can be a relatively dense oxide layer adjacent to the quantum dots 120 to provide protection.

In some embodiments, the first protective layer 210 is an inorganic oxide layer formed by the ALD process, and the second protective layer 220 is an inorganic oxide layer formed by the sol-gel process. The porosity of the second protective layer 220 is greater than that of the first protective layer 210, wherein the porosity of the second protective layer 220 defined in the present disclosure is the ratio of the volume of pores to the total volume of the second protective layer 220, and the porosity of the first protective layer 210 defined in the present disclosure is the ratio of the volume of pores to the total volume of the first protective layer 210. Therefore, the first protective layer 210 can effectively block moisture and/or oxygen, and the pores of the second protective layer 220 can capture moisture and oxygen in the environment so the moisture and oxygen do not contact the quantum dots 120 easily. Besides, since the second protective layer 220 has a larger porosity, the second protective layer 220 has better toughness and cannot be broken easily, thereby providing a buffer to protect the quantum dots 120.

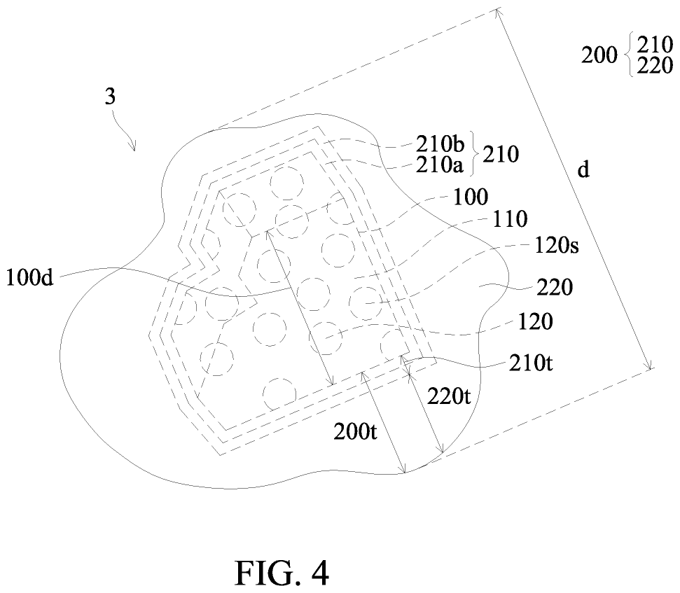

FIG. 4 is a perspective view showing the quantum dot composite structure 3 according to some embodiments of the present disclosure. As shown in FIG. 4, in some embodiments, the first protective layer 210 may comprise a plurality of sublayers. In some embodiments, the number of the sublayers can be any natural number, such as but not limited to 1-5. For example, when the number of the sublayers is 1, the first protective layer 210 is a single-layer structure. When the number of the sublayers is greater than 1, the first protective layer 210 is a multi-sublayer structure. For convenience of explanation, in some embodiments, FIG. 4 shows that the number of the sublayers of the first protective layer 210 is 2, which means that the first protective layer 210 includes the first sublayer 210a and the second sublayer 210b. However, the disclosure is not limited to this. In some embodiments, the first sublayer 210a can be on the glass particle 100, the second sublayer 210b can be on the first sublayer 210a, and the second protective layer 220 can be on the second sublayer 210b. Furthermore, to avoid the problem of a decrease in carrier transmission efficiency and poor luminescence efficiency of quantum dots caused by excessive thickness, the total thickness of the first and second protective layers is less than or equal to 500 nm. In some embodiments, each sublayer may be formed by the same or different materials. For example, the sublayer may include silicon oxide, aluminum oxide, or a combination thereof.

The examples of the quantum dot composite structures are provided in the following description and Table 1. Example 1 represents the quantum dot composite structure 2 as shown in FIG. 3. Example 2 represents the quantum dot composite structure 3 as shown in FIG. 4.

TABLE 1

| | | Example 1 | | Example 2 | |
|---|---|---|---|---|---|
| Types of glass matrix | | borosilicate glass | | borosilicate glass | |
| Types of quantum dots | | perovskite quantum dots | | perovskite quantum dots | |
| Average diameter of | | 40 | μm | 38 | μm |
| glass particles | | | | | |
| First | Material | SiO₂ | | SiO₂ & Al₂O₃ | |
| protective | Thickness | 4.5 | nm | 12 | nm |
| layer | Number of | 1 | | 2 | |
| | sublayers | | | | |
| | Thickness of | — | | First sublayer (SiO₂): 4.5 nm | |
| | each sublayer | | | Second sublayer (Al₂O₃): 7.5 nm | |
| Second | Material | SiO₂ | | SiO₂ | |
| protective | Thickness | 11 | nm | 25 | nm |
| layer | | | | | |

In Example 1, approximately 2.5 g of glass particles 100 which had been selected by the particle size screening process were placed in an ALD apparatus. By reacting tris(dimethylamino)silane (TDMAS) with ozone at 80° C., the dense SiO₂ layer is synthesized by the ALD process to be formed as the first protective layer 210 on the surface of the glass particles 100. Next, approximately 2.0 g of glass particles which had been modified by the ALD process were placed in 30 mL of n-hexane, followed by adding 20 mL of polydimethylsiloxane (PDMS), 4 mL of tetraethoxysilane (TEOS), 2 mL of dibutyltin dilaurate (DBTL), and stirred for approximately 30 minutes. Then, 0.020 g of 2,2′-azobis(2-methylpropertitrile) (AIBN) was added as the initiator of the reaction and refluxed at 85° C. for 4 hours, and the loose and thick SiO₂ layer is synthesized by the sol-gel process to be formed as the second protective layer 220 on the surface of the ALD-modified glass particles 100, thus the quantum dot composite structure 2 of Example 1 is obtained. Besides, the quantum dot composite structure 2 can be further cleaned with n-hexane and dried at 60° C. In Example 2, the ALD process is repeated twice to form two sublayers of the first protective layer 210 while the other steps are the same to form the quantum dot composite structure 3 of Example 2. The repeated ALD processes can use different precursors to form different sublayers of the first protective layer 210. For example, the precursor may further include trimethylaluminum (TMA) to form aluminum oxide. In some embodiments, the first protective layer 210 may include a first sublayer 210a comprising SiO₂ and a second sublayer 210b comprising Al₂O₃. For example, after forming the first sublayer 210a of the first protective layer 210 with TDMAS and ozone, aluminum oxide layer is formed by the ALD process and as the second sublayer 210b on the surface of the first sublayer 210a to provide a relatively dense aluminum oxide layer by reacting TMA with water vapor at 80° C. In some embodiments, regarding the process parameters of forming Al₂O₃ layer as the second sublayer 210b by the ALD process, a rotational speed of a quartz tube may be set to 2 rpm, a reaction temperature may be set to 80° C., and a carrier gas flow rate may be set to 5 sccm. Next, the following steps are performed: (1) spray TMA into the quartz tube for 0.015 seconds and wait for 20 seconds, then spray TMA for 0.015 seconds again and repeat step (1) three times; (2) spray water vapor into the quartz tube for 0.015 seconds and wait for 20 seconds, then spray water vapor for 0.015 seconds again and repeat step (2) three times. A cycle includes repeating both steps (1) and (2) once, and in some embodiments, in order to adjust the coating thickness of aluminum oxide as the second sublayer 210b on the first sublayer 210a, the cycle including both of the steps (1) and (2) can be repeated 40-100 times. Then, a second protective layer 220 can be formed on the first protective layer 210 (including the first sublayer 210a and the second sublayer 210b) by means of the aforementioned method.

In the following description, Example 1 was analyzed, but the present disclosure is not limited to this. Example 2 and other content described in the present disclosure can also have the effect of the subsequent analysis.

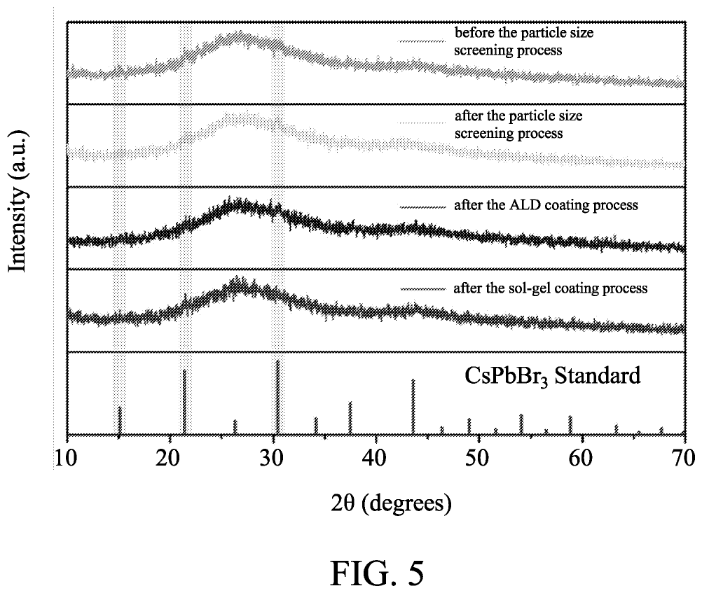

FIG. 5 is an X-ray diffraction (XRD) analysis pattern showing the various stages in a method of forming a quantum dot composite structure 2 according to some embodiments of the present disclosure (Instrument Brand and Model: Bruker D2 Phase Diffractometer). FIG. 5 illustrates XRD patterns of the CsPbBr 3 standard, glass particles before the particle size screening process, glass particles after the particle size screening process, glass particles after the ALD coating process, and glass particles after the sol-gel coating process. The glass particles after the sol-gel coating process means that the glass particles have been coated by the ALD process first and then are coated by the sol-gel process.

As shown in FIG. 5, the main crystal phase of each stage is green all-inorganic perovskite QDs CsPbBr₃. There are diffraction peaks at 15° to 30° in stages of “before the particle size screening process,” “after the particle size screening process,” and “after the ALD coating process.” This confirms the existence of CsPbBr₃ quantum dots. However, after the glass particles are coated by the sol-gel process, the SiO₂ layer as the second protective layer 220 is thick and the diffraction signal mainly comes from the second protective layer 220, which makes it difficult to detect the diffraction signal of CsPbBr₃ crystal, thus confirming that the second protective layer 220 has been successfully formed.

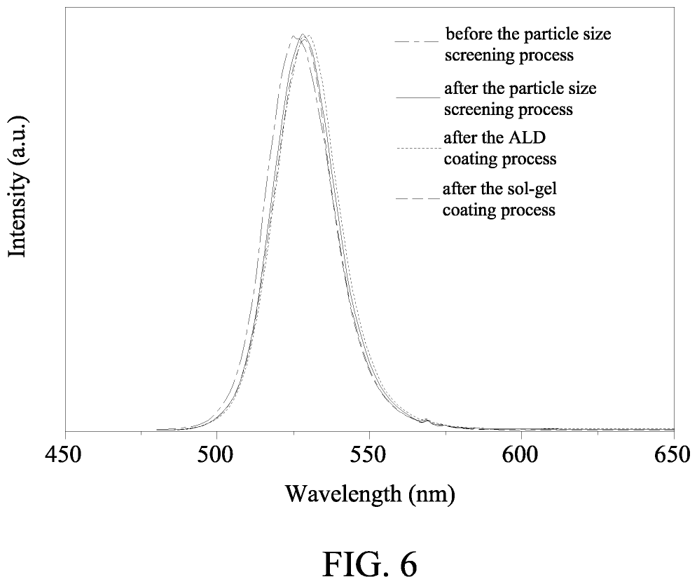

FIG. 6 illustrates fluorescence spectrums of various stages in a method of forming a quantum dot composite structure 2 according to some embodiments of the present disclosure (Instrument Brand and Model: Edinburgh Instrument FLS1000 Photoluminescence Spectrometer). As shown in FIG. 6, before the particle size screening process, the emission peak of the glass particles is 525 nm, the quantum dot efficiency is 45.6% and FWHM is 24.6 nm. After the particle size screening process, the emission peak of the glass particles is 528 nm, the quantum dot efficiency is 49.2% and FWHM is 24.0 nm. After the ALD coating process, the emission peak of the glass particles is 530 nm, the quantum dot efficiency is 45.9% and FWHM is 23.6 nm. After the sol-gel coating process, the emission peak of glass particles is 530 nm, the quantum dot efficiency is 44.0% and FWHM is 23.6 nm. The result shows that the fluorescence emission peak of each stage is located at 525 nm-530 nm without significant red shift, and there is no significant change about FWHM of the emission peak, which shows that the temperature of the ALD process and the sol-gel process does not damage the CsPbBr₃ quantum dot.

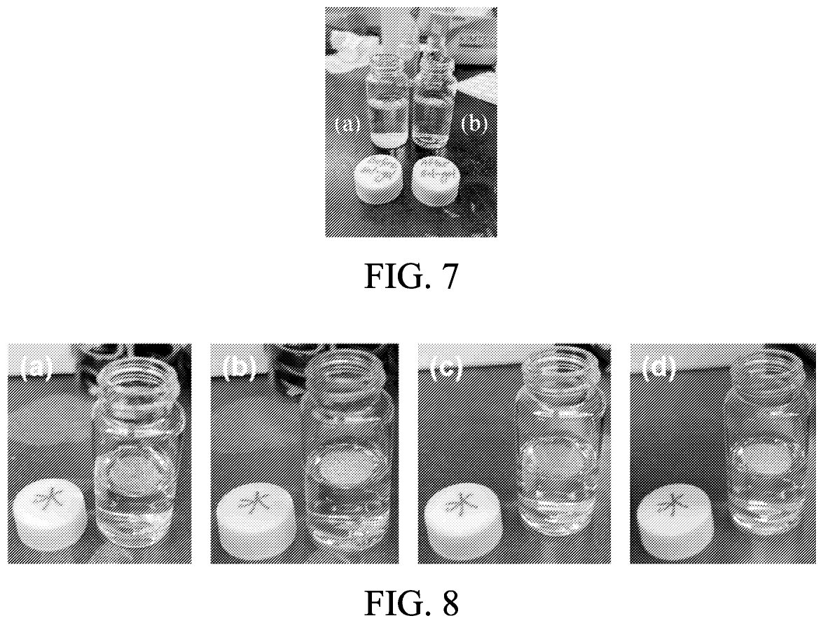

FIG. 7 illustrates a hydrophobicity test image of various stages in a method of forming a quantum dot composite structure according to some embodiments of the present disclosure. FIG. 7(a) is an image of glass particles that have been selected by the particle size screening process immersed in the distilled water. FIG. 7(b) is an image of glass particles that have coated by the sol-gel process immersed in the distilled water. FIG. 7(a) shows that glass particles were immersed in water and quickly settled to the bottom of the bottle in large quantities. FIG. 7(b) shows that the glass particles of Example 1 float on the water surface, representing the quantum dot composite structure 2 of Example 1 with high hydrophobicity and high water-resistant ability.

FIG. 8 shows the hydrophobicity test images of various stages in a method of forming a quantum dot composite structure according to some embodiments of the present disclosure. FIG. 8(a) is an image photographed under visible light which shows that the glass particles coated by the sol-gel process were immersed in distilled water on the day. FIG. 8(b) is an image photographed under visible light which shows that the glass particles coated by the sol-gel process were irradiated by ultraviolet light on the day. FIG. 8(c) is an image photographed under visible light which shows that the glass particles coated by the sol-gel process were immersed in the distilled water for one day. FIG. 8(d) is an image photographed under visible light which shows that the glass particles coated by the sol-gel process were immersed in the distilled water for one day and irradiated by ultraviolet light. In FIG. 8(d), the glass particles were photographed immediately after being exposed to ultraviolet light for 30 seconds. As shown in FIG. 8(c) and FIG. 8(d), after the glass particles were immersed in the distilled water for one day, the quantum dot composite structures still floated on the water surface without significant changes in appearance and color, and can still emit strong fluorescent light after being irradiated by ultraviolet light. It shows that the quantum dot composite structure 2 of Example 1 can provide high hydrophobicity and high water-resistant ability, and can protect the internal CsPbBr₃ quantum dots.

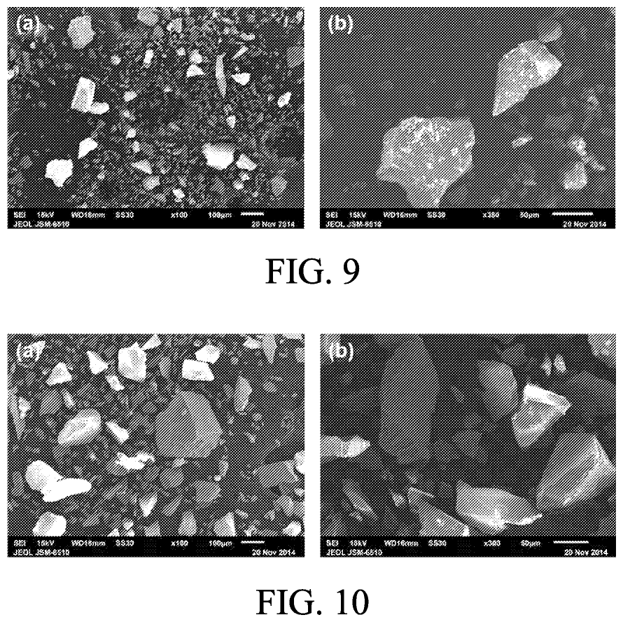

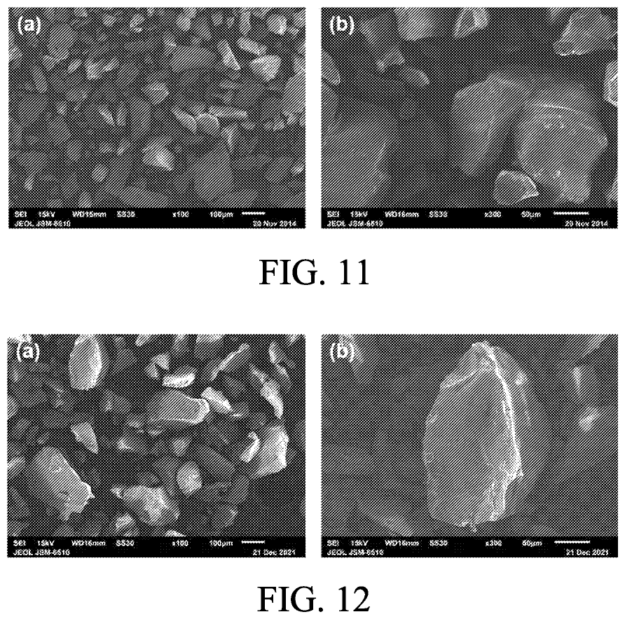

FIGS. 9-12 respectively illustrate scanning electron microscope (SEM) images of various stages in a method of forming a quantum dot composite structure according to some embodiments of the present disclosure (Instrument Brand and Model: JEOL JSM-6510 scanning electron microscope). Among them, FIG. 9 shows SEM images of glass particles in different scales before the particle size screening process, FIG. 10 shows SEM images of glass particles in different scales after the particle size screening process, FIG. 11 shows SEM images of glass particles in different scales after the ALD coating process, and FIG. 12 shows SEM images of glass particles in different scales after the sol-gel coating process.

FIG. 9 shows that the particle size distribution of the glass particles is wide and there are many impurities on the surface of the particles before the particle size screening process. FIG. 10 shows that the particle surface is cleaner and the particle size distribution is more concentrated after the particle size screening process. The thickness of the first and second protective layers cannot be clearly determined from the SEM images of FIGS. 11 and 12. Therefore, the first and second protective layers 210 and 220 are further analyzed by using infrared absorption spectrums and transmission electron microscope (TEM) images.

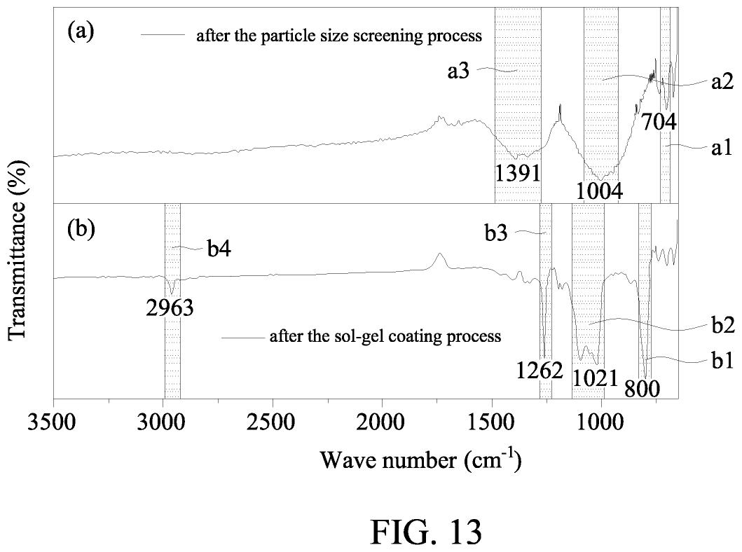

FIG. 13 illustrates an infrared absorption spectrum of various stages in a method of forming a quantum dot composite structure according to some embodiments of the present disclosure (Instrument Brand and Model: PerkinElmer Spectrum Two FT-IR L160000F). FIG. 13(a) shows the absorption spectrum of glass particles after particle size screening process. FIG. 13(b) shows the absorption spectrum of the quantum dot composite structures after the sol-gel coating process.

As shown in FIG. 13, the absorption signals of B—O and Si—O bonds can be measured because the glass particles include perovskite quantum dots CsPbBr₃. The C—H bond, C—O bond, Si—O bond and other absorption signals can be measured because the quantum dot composite structure includes a SiO₂ layer after the ALD coating process and the sol-gel coating process and the SiO₂ layer is polymerized from polydimethylsiloxane and tetraethoxysilane. FIG. 13(a) shows vibration absorptions of the B—O—B bond, Si—O—Si bond, and [BO₃] units at 704 cm⁻¹, 1004 cm⁻¹, and 1391 cm⁻¹, respectively. FIG. 13(b) shows absorption peaks at 800 cm⁻¹, 1021-1097 cm⁻¹, 1262 cm⁻¹, and 2963 cm⁻¹, respectively. The absorption peak at 800 cm⁻¹ represents the vibration absorption of the Si—O bond, the absorption peak at 1021-1097 cm⁻¹ represents the vibration absorption of the Si—O—Si bond and the stretching vibration absorption of the C—O bond, the absorption peak at 1262 cm⁻¹ represents the stretching vibration absorption of the C—O bond, and the absorption peak at 2963 cm⁻¹ represents the stretching vibration absorption of the C—H bond. Therefore, FIG. 13(b) confirms that the quantum dot composite structure 2 includes CsPbBr₃ quantum dots 120 and a SiO₂ protective layer 200.

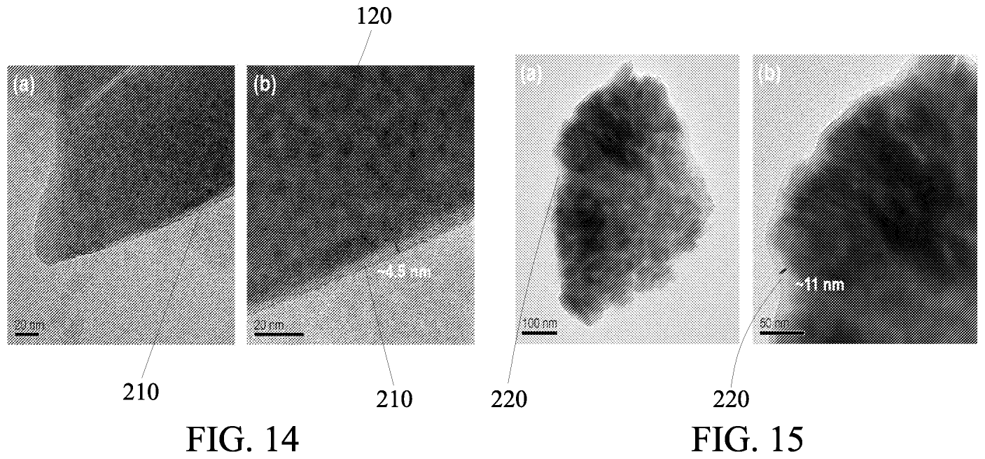

FIGS. 14 and 15 respectively illustrate transmission electron microscopy (TEM) images of various stages in a method of forming a quantum dot composite structure according to some embodiments of the present disclosure. (Instrument Brand and Model: JEOL JEM 2100F transmission electron microscope). FIG. 14 shows TEM images of glass particles in different scales after the ALD coating process, and FIG. 15 shows TEM images of glass particles in different scales after the sol-gel coating process.

As shown in FIG. 14(a), a large number of CsPbBr₃ perovskite quantum dots 120 (dark black particles) are distributed within the glass matrix 110 (black block), and the outer side of the glass matrix is coated with a flat SiO₂ thin layer (gray region) as the first protective layer. As shown in FIG. 14(b), the thickness 210t of the first protective layer 210 is approximately 4.5 nm. As shown in FIG. 15(a), a nanoscale SiO₂ thin film (gray region) is further coated as the second protective layer 220. As shown in FIG. 15(b), the thickness 220t of the second protective layer 220 is approximately 11 nm. Therefore, FIG. 15(b) confirms that the quantum dot composite structure 2 includes CsPbBr₃ quantum dots 120, the first protective layer 210, and the second protective layer 220.

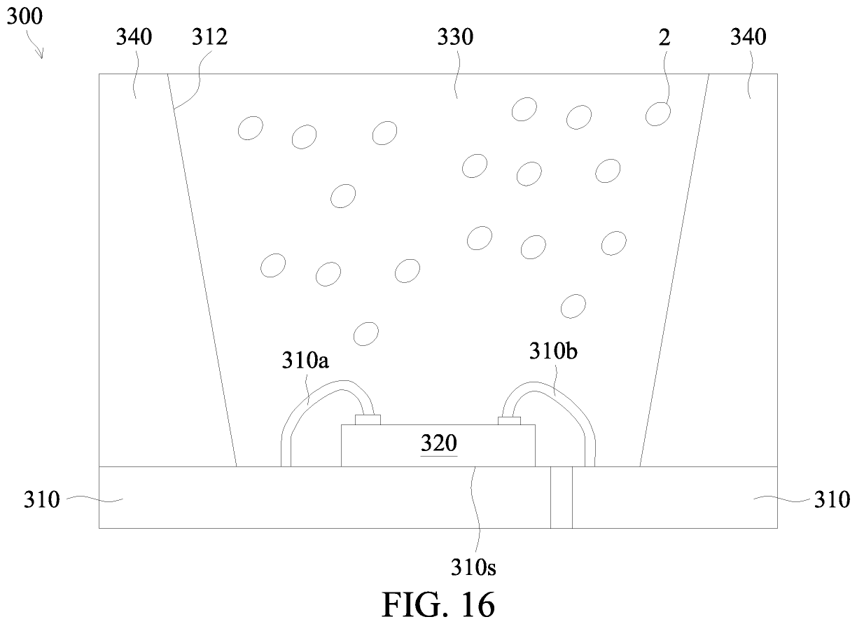

The quantum dot composite structure disclosed in the present disclosure can be applied to various light-emitting devices, such as light-emitting diode devices, illumination devices, backlight modules of displays, and pixels of a display. Take the light-emitting diode device as an example, FIG. 16 is a schematic view of a light-emitting device according to some embodiments of the present disclosure. In some embodiments, a light-emitting diode device 300 includes a base 310, a light emitting diode (LED) chip 320, a wavelength conversion layer 330, and a reflection wall 340. The base 310 has a positive electrode 310a and a negative electrode 310b. The upper surface of the base 310 has a die bonding region 310s, and the reflection wall 340 is located on the base 310 surrounding the die bonding region 310s and defines an accommodation space 312. The LED chip 320 is located in the accommodation space 312 and fixed on the die bonding region 310s of the base 310. The LED chip 320 can emit blue or UV light. In addition, the LED chip 320 can be a small-sized LED chip, such as a sub millimeter LED chip or a micro LED chip. The LED chip 320 can be installed in a face-up type as shown in FIG. 16, or in a flip-chip type according to the requirements. The wavelength conversion layer 330 is located on the light emission surface of the LED chip 320 and includes a transparent material 332 mixed with the quantum dot composite structures 2 shown in FIG. 2 or the quantum dot composite structures 3 shown in FIG. 3. In some embodiments, the transparent material 332 can be polydimethylsiloxane (PDMS), epoxy resin, silicone, or any combination thereof.

According to some embodiments of the present disclosure, in addition to the quantum dot composite structures 2 or 3 disclosed in the embodiments of the present disclosure, the wavelength conversion layer 330 may mix other phosphors or quantum dot composite structures 2 (or 3) that emit different colors according to color requirements. Taking the LED device 300 emitting white light as an example, the LED chip 320 emits blue light, and the wavelength conversion layer 330 includes green quantum dot composite structures 2 and red quantum dot composite structures 2. Taking the LED device 300 emitting white light as an example, the LED chip 320 emits UV light, and the wavelength conversion layer 330 includes blue quantum dot composite structures 2, green quantum dot composite structures 2, and red quantum dot composite structures 2. In some embodiments, the quantum dots 120 of the blue light quantum dot composite structures 2 are blue all-inorganic perovskite quantum dots CsPb(ClaBr₁₋ₐ)₃ wherein 0<a≤1. In some embodiments, the quantum dots 120 of the green light quantum dot composite structure 2 are green all-inorganic perovskite quantum dots CsPb(Br_{1-b}I_{b})₃ wherein 0≤b<0.5. In some embodiments, the quantum dots 120 of the red all-inorganic perovskite quantum dot composite structure 2 are red all-inorganic perovskite quantum dots CsPb(Br_{1-b}I_{b})₃ wherein 0.5≤b≤1.

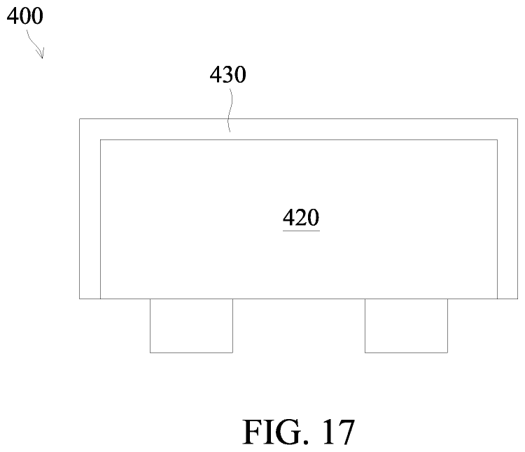

Furthermore, the light-emitting diode device can be various types and is not limited to the light-emitting diode device 300 shown in FIG. 16. As shown in a schematic view of another LED device in FIG. 17, the light-emitting diode device 400 includes an LED chip 420 and a wavelength conversion layer 430. The LED chip 420 is in a flip-chip type, and the wavelength conversion layer 430 includes quantum dot composite structures 2 (or 3) and transparent material. The wavelength conversion layer 430 can conformally cover the upper surface and side walls of the LED chip 320. In some embodiments, the material of the wavelength conversion layer 430 is the same or different from that of the wavelength conversion layer 330.

In summary, according to some embodiments of the present disclosure, a quantum dot composite structure including a protective layer and a forming method thereof are provided, thereby further enhancing the stability of quantum dots. Specifically, even if quantum dots are located in a glass matrix, the glass matrix will still expose at least a portion of the exposed surface of the quantum dots, leading to their degradation due to environmental factors. Therefore, by using an inorganic protective layer to cover the exposed surface of quantum dots, the ability of quantum dots to resist environmental factors can be improved, such as improving their resistance to water vapor and oxygen, to maintain the luminescent performance of quantum dots. Furthermore, in some embodiments, the protective layer may further include a first protective layer and a second protective layer. By combining different parameters of the first and second protective layers, such as density, crystallinity, thickness, porosity, and material type, the ability of quantum dots to resist environmental factors can be improved.

Further, the features, benefits, and characteristics described in the present disclosure may be combined in any suitable manner in one or more embodiments. According to the description herein, those having ordinary knowledge in the art to which the present disclosure belongs will realize that the present disclosure can be implemented without one or more of particular features or benefits of a particular embodiment. In other instances, additional features and benefits may be shown in some embodiments while they may not be shown in all embodiments of the present disclosure.

The components in the embodiments of the present disclosure can be mixed or used in a combination as long as they do not violate the spirit of the present disclosure or conflict with each other. In addition, the protection scope of the present disclosure is not limited to the processes, machines, manufacturing, material composition, devices, methods, and steps in the specific embodiments described in the specification. Any ordinary knowledge in this field can understand the current or future developed processes, machines, manufacturing, material composition, devices, methods, and steps from the present disclosure. As long as substantially the same functionality or results can be achieved in the embodiments described here, they can be used in accordance with the present disclosure. Therefore, the protection scope of the present disclosure includes the above-mentioned processes, machines, manufacturing, material composition, devices, methods, and steps. Any embodiment or claim disclosed in the present disclosure is not required to achieve all the purposes, advantages, and/or characteristics disclosed in the present disclosure.

The components of the embodiments are outlined above so that those having ordinary knowledge in the art to which the present disclosure belongs may better understand the perspective of the embodiments of the present disclosure. Those having ordinary knowledge in the art to which the present disclosure belongs should understand that they can design or modify other processes or structures based on the embodiments of the present disclosure to achieve the same purposes and/or advantages as the embodiments described herein. Those having ordinary knowledge in the art to which the present disclosure belongs should also understand that such equivalent structures are not inconsistent with the spirit and scope of the present disclosure, and that they can make various changes, substitutions, and replacements without violating the spirit and scope of the present disclosure. Therefore, the scope of protection of the present disclosure is defined by the scope of the claim attached hereto. In addition, although several preferred embodiments are disclosed in the present disclosure, they are not intended to limit the present disclosure.

What is claimed is:

1. A quantum dot composite structure, comprising:
a glass particle including a glass matrix and a plurality of quantum dots located in the glass matrix, wherein at least one of the plurality of quantum dots includes an exposed surface in the glass matrix; and
an inorganic protective layer disposed on the glass particle and covering the exposed surface.

2. The quantum dot composite structure as claimed in claim 1, wherein a thickness of the inorganic protective layer is greater than or equal to 1 nm and less than or equal to 500 nm.

3. The quantum dot composite structure as claimed in claim 1, wherein the inorganic protective layer comprises inorganic oxide.

4. The quantum dot composite structure as claimed in claim 1, wherein the glass matrix comprises phosphosilicate glass, tellurite glass, borosilicate glass, borogermanate glass or combinations thereof.

5. The quantum dot composite structure as claimed in claim 1, wherein the inorganic protective layer comprises:
a first protective layer covering the glass particle and directly contacting the exposed surface; and
a second protective layer disposed on the first protective layer, wherein the first protective layer is located between the glass particle and the second protective layer.

6. The quantum dot composite structure as claimed in claim 5, wherein a thickness of the first protective layer is less than that of the second protective layer.

7. The quantum dot composite structure as claimed in claim 5, wherein a density of the first protective layer is larger than that of the second protective layer.

8. The quantum dot composite structure as claimed in claim 5, wherein the first protective layer comprises a plurality of sublayers.

9. The quantum dot composite structure as claimed in claim 5, wherein a shape of the first protective layer is conformal to that of the glass particle.

10. The quantum dot composite structure as claimed in claim 5, wherein the first protective layer is an inorganic oxide layer formed by an atomic layer deposition process and the second protective layer is an inorganic oxide layer formed by a sol-gel process.

11. The quantum dot composite structure as claimed in claim 1, wherein an emission wavelength of the plurality of quantum dots is larger than or equals to 300 nm and less than or equals to 800 nm.

12. A method of forming a quantum dot composite structure, comprising:
providing a glass particle comprising a plurality of quantum dots;
forming a first protective layer on the glass particle by an atomic layer deposition (ALD) process to make the first protective layer cover the glass particle conformally; and
forming a second protective layer on the first protective layer by a sol-gel process to make the second protective layer cover the first protective layer.

13. The method as claimed in claim 12, wherein a reaction temperature of the ALD process and the sol-gel process is larger than or equals to 60° C. and less than or equals to 180° C.

14. The method as claimed in claim 13, wherein tris(dimethylamino)silane and ozone react at a temperature greater than or equal to 75° C. and less than or equal to 90° C. to form the first protective layer during the ALD process.

15. The method as claimed in claim 13, wherein azobisisobutyronitrile (AIBN) is used as an initiator to make polydimethylsiloxane (PDMS), tetraethoxysilane (TEOS), and dibutyltin dilaurate (DBTL) react at a temperature greater than or equal to 75° C. and less than or equal to 90° C. to form the second protective layer during the sol-gel process.

16. The method as claimed in claim 12, wherein the step of providing the glass particle further comprises:
forming a glass bulk by a melt-quench process;
performing a grinding process to break the glass bulk into the glass particles; and
performing a particle size screening process to select the glass particles with an average diameter greater than or equal to 20 μm and less than or equal to 50 μm.

17. The method as claimed in claim 12, wherein a thickness of the first protective layer is less than that of the second protective layer.

18. The method as claimed in claim 12, wherein a total thickness of the first protective layer and the second protective layer is less than or equal to 500 nm.

19. The method as claimed in claim 12, wherein a density of the first protective layer is larger than that of the second protective layer.

20. The method as claimed in claim 12, wherein the step of forming the first protective layer comprises forming a plurality of sublayers.
